(19) United States
(12) Patent Application Publication
(10) Pub. No.: US 2026/0371737 A1
(43) Pub. Date: Nov. 19, 2026

(54) PAD PORTION AND DISPLAY DEVICE COMPRISING THE SAME

(71) Applicant: LG Display Co., Ltd., Seoul (KR)

(72) Inventor: Jeong-Gyun SHIN, Paju-si (KR)

(73) Assignee: LG Display Co., Ltd., Seoul (KR)

(21) Appl. No.: 19/540,304

(22) Filed: Feb. 13, 2026

(30) Foreign Application Priority Data
May 13, 2025 (KR) 10-2025-0061769

(51) Int. Cl. H10D 86/60

(52) U.S. Cl. CPC H10D 86/60

(57) ABSTRACT

A pad portion includes a pad electrode, a plurality of insulating films spaced apart from each other on the pad electrode and exposing a portion of an upper surface of the pad electrode, a light separation layer disposed on an upper surface of the pad electrode exposed by the plurality of insulating films, and an encapsulating film disposed on the light separation layer. The light separation layer is configured to be separated from the pad electrode when irradiated with a laser, thereby facilitating removal of the encapsulating film while minimizing damage to the insulating films. A display device including the pad portion is also provided.

### CROSS-REFERENCE TO RELATED APPLICATIONS

This application claims the benefit of priority of the Korean Patent Application No. 10-2025-0061769 filed on May 13, 2025, which is hereby incorporated by reference as if fully set forth herein.

### BACKGROUND

### Technical Field

The present disclosure relates to a pad portion and a display device including the same.

### Description of the Related Art

As the information society advances, demand for display devices for displaying images is increasing in various forms. Accordingly, various display devices such as liquid crystal displays (LCDs), plasma display panels (PDPs), organic light-emitting displays (OLEDs), and quantum dot light-emitting displays (QLEDs) are being utilized in recent years.

To output an image from a pixel within the display panel, a pad portion within the display panel can supply power and/or signals from a driver integrated circuit (IC) to the display panel.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### BRIEF SUMMARY

When manufacturing a display panel, a process is required to selectively remove the encapsulating film by applying a laser to the top of the pad portion to connect the drive integrated circuit and the pad portion of the display panel.

However, since the length of the pad portion is very short considering the precision of the laser equipment, it is a difficult process to irradiate the laser only to the pad portion.

One embodiment of the present disclosure provides a pad portion in which a peeling reaction occurs at a pad electrode of the pad portion before the insulating film is damaged by a laser by including a light separation layer.

One embodiment of the present disclosure provides a pad portion in which damage to an insulating film is minimized by including a light separation layer.

Another embodiment of the present disclosure is to provide a display device including such a pad portion.

One embodiment of the present disclosure for achieving the above-described technical task provides a pad portion further comprising: a pad electrode; a plurality of insulating films spaced apart from each other on the pad electrode and exposing a portion of an upper surface of the pad electrode; a light separation layer disposed on an upper surface of the pad electrode exposed by the plurality of insulating films; and an encapsulating film disposed on the light separation layer.

The light separation layer may include a first light separation layer disposed spaced apart from the insulating film.

The first light separation layer may include at least one of an inorganic material, and an organic material. The inorganic material may include a metal material.

The metal material may include silver (Ag).

The inorganic material may include either silicon nitride (SiNx) or silicon oxide (SiOx).

The organic material may include an organic material doped with an N-type dopant or an organic material doped with a P-type dopant.

The first light separation layer may include a first layer made of one of a metal material and a non-metal material in the inorganic material; and a second layer made of the other of the metal material and a non-metal material in the inorganic material and disposed on the first layer.

The light separation layer may include a second light separation layer disposed in contact with the insulating film.

The second light separation layer can cover the side and upper surfaces of the insulating film.

The second light separation layer includes an inorganic material, and the inorganic material may include any one of silicon nitride (SiNx) and silicon oxide (SiOx).

The light separation layer can be peeled off from the pad electrode when irradiated with a laser.

The insulating film may include a first insulating film and a second insulating film disposed on the first insulating film, and the encapsulating film may include a first encapsulating film and a second encapsulating film disposed on the first encapsulating film.

Another embodiment of the present disclosure provides a display device including the pad portion.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a plan view of a display device according to one embodiment of the present disclosure.

FIG. 2 is a cross-sectional view of a pad portion according to one embodiment of the present disclosure.

FIG. 3 is a cross-sectional view of a pad portion according to another embodiment of the present disclosure.

FIG. 4 is a cross-sectional view of a pad portion according to another embodiment of the present disclosure.

FIG. 5 is a cross-sectional view of a pad portion according to another embodiment of the present disclosure.

FIG. 6 is a drawing showing the laser process of the present disclosure.

FIG. 7 is an image showing the planar shape of a pad portion according to one embodiment of the present disclosure.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only~’ is used. The terms of a singular form may include plural forms unless referred to the contrary.

In construing an element, the element is construed as including an error band although there is no explicit description.

In describing a position relationship, for example, when the position relationship is described as ‘upon~’, ‘above~’, ‘below~’ and ‘next to~’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to

encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

Any implementation described herein as an “example” is not necessarily to be construed as preferred or advantageous over other implementations.

Also, when an element or layer is “connected,” “coupled,” or “adhered” to another element or layer denotes that the element or layer can not only be directly connected or adhered to the other element or layer, but also be indirectly connected or adhered to the other element or layer with one or more intervening elements or layers “disposed,” or “interposed” between the elements or layers, unless otherwise specified. It should be understood to mean that elements may be so disposed to directly contact each other, or may be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

In the addition of reference numerals to the components of each drawing describing embodiments of the present disclosure, the same components can have the same sign as can be displayed on the other drawings.

The disclosure is directed to a pad portion that includes a light separation layer disposed on an exposed upper surface of a pad electrode and beneath an encapsulating film. The light separation layer is configured to preferentially absorb laser energy and peel from the pad electrode when irradiated, so that removal during laser processing begins at the pad electrode region rather than at adjacent insulating films. By controlling the order in which layers are removed, the structure addresses manufacturing difficulties that arise from limited laser alignment precision and reduces the likelihood of premature damage to insulating films.

The light separation layer is selectively arranged in an open area of the pad portion and, in certain embodiments, is spaced apart from the insulating films to prevent unintended electrical conduction. Various material options are disclosed, including metal materials, inorganic materials, and doped organic materials, each selected for favorable laser response characteristics rather than electrical functionality. Additional embodiments include multilayer separation structures and an optional secondary separation layer formed of an inorganic material that covers side and upper surfaces of the insulating films to further mitigate laser induced damage.

At the device level, the pad portion is incorporated into a display device without modification to pixel structures or driving circuitry. The disclosed configuration improves process reliability by ensuring that the encapsulating film and separation layer are removed in a controlled manner while maintaining the integrity of underlying insulating films and wiring. As a result, connection between the pad electrode and external circuitry can be achieved more reliably, contributing to improved manufacturing yield and device reliability.

Hereinafter, examples of the present disclosure will be described with reference to the attached drawings and examples. The scales of the components illustrated in the drawings are different from the actual scale for convenience of explanation, and are therefore not limited to the scales illustrated in the drawings.

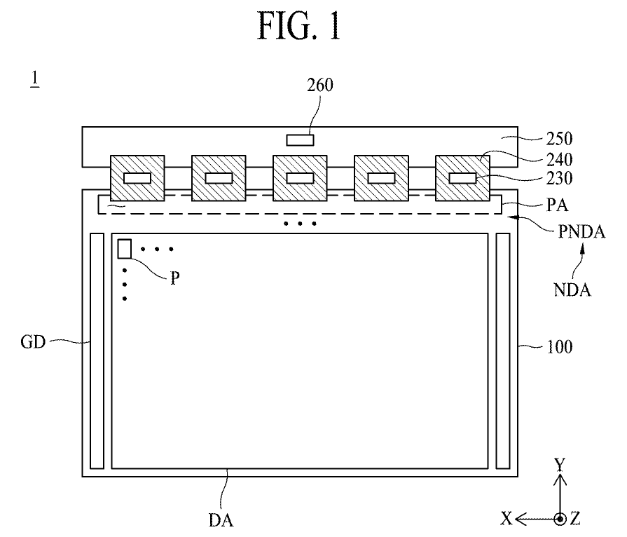

FIG. 1 is a plan view of a display device (1) according to one embodiment of the present disclosure.

Referring to FIG. 1, the display device (1) may include a display panel including a gate driver (GD), a source driver integrated circuit (230), a flexible film (240), a circuit board (250), and a timing control unit (260).

The display panel according to the present disclosure may include a substrate (100). The substrate (100) includes a thin film transistor and may be a transistor array substrate, a lower substrate, a base substrate, or a first substrate. The substrate (100) may be a transparent glass substrate or a transparent plastic substrate. For example, the substrate (100) may be a transparent glass substrate.

The display panel according to the present disclosure may include a counter substrate (not shown). The counter substrate may be connected to the substrate (100) via a transparent connecting member (not shown).

According to one embodiment of the present disclosure, the substrate (100) may include a display area (DA) and a non-display area (NDA).

The display area (DA) is the area where an image is displayed, and may be a pixel array area, an active area, a pixel array unit, a display unit, or a screen. For example, the display area (DA) may be positioned in the central portion of the display panel.

The display area (DA) according to one embodiment of the present disclosure may include gate lines, data lines, pixel driving power lines, and a plurality of pixels (P). Each of the plurality of pixels (P) may include a plurality of sub-pixels that may be defined by gate lines and data lines.

A non-display area (NDA) is an area where no image is displayed, and may be a peripheral circuit area, a signal supply area, an inactive area, or a bezel area. The non-display area (NDA) may be configured to be around the display area (DA). That is, the non-display area (NDA) may be disposed to surround the display area (DA).

The display device (1) according to one embodiment of the present specification may have a pad portion (PA) disposed in a non-display area (NDA). The pad portion (PA) may supply power and/or signals for a pixel (P) provided in the display area (DA) to output an image. The pad portion (PA) may correspond to a pad portion (10, 11, 12, 13) described below.

The gate driver (GD) supplies gate signals to the gate lines according to the gate control signal input from the timing control unit (260). The gate driver (GD) may be formed in a GIP (gate driver in panel) manner on one side of the display area (DA) of the display panel or, as shown in FIG. 1, in a non-display area (NDA) outside both sides of the display area (DA). Alternatively, the gate driver (GD) may be manufactured as a driving chip, mounted on a flexible film, and attached to a non-display area (NDA) outside one side or both sides of the display area (DA) of the display panel using a TAB (tape automated bonding) manner.

The source driver integrated circuit (230) receives digital video data and source control signals from the timing control unit (260). The source driver integrated circuit (230) converts the digital video data into analog data voltages in response to the source control signals and supplies the analog data voltages to data lines. When the source driver integrated circuit (230) is fabricated as a driving chip, it may be mounted on the flexible film (240) in a chip-on-film (COF) or chip-on-plastic (COP) manner.

Pads such as data pads may be formed in a non-display area (NDA) of the display panel. The flexible film (240) may include wirings that connect the pads to the source driver integrated circuit (230), and wirings that connect the pads to wirings of the circuit board (250). The flexible film (240) may be attached onto the pads using an anisotropic conducting film (ACF), such that the pads are electrically connected to the wirings of the flexible film (240).

The circuit board (250) may be attached to the flexible films (240). The circuit board (250) may have a plurality of circuits implemented with driving chips mounted thereon. For example, a timing control unit (260) may be mounted on the circuit board (250). The circuit board (250) may be a printed circuit board (PCB) or a flexible printed circuit board (FPCB).

The timing control unit (260) receives digital video data and timing signals from an external system board through a cable of the circuit board (250). The timing control unit (260) generates gate control signals for controlling operation timing of the gate driver (GD) and source control signals for controlling the source driver integrated circuits (230) based on the timing signals. The timing control unit (260) supplies the gate control signals to the gate driver (GD) and supplies the source control signals to the source driver integrated circuits (230).

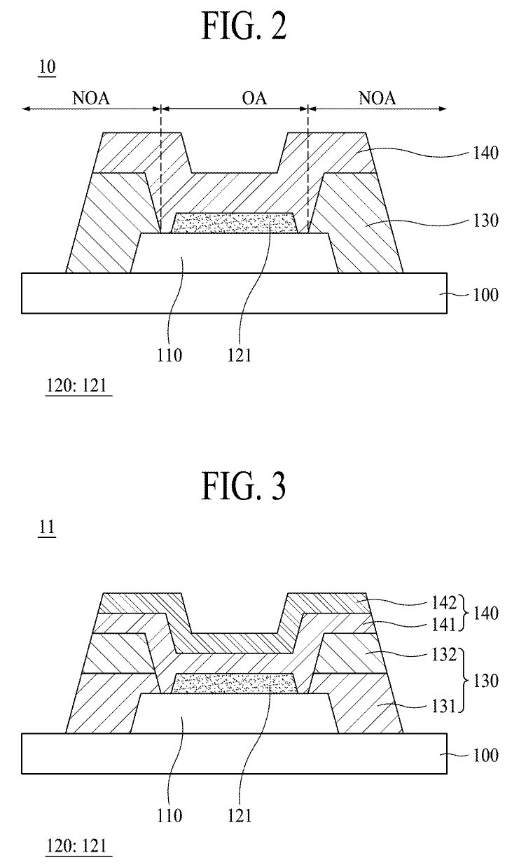

FIG. 2 is a cross-sectional view of a pad portion (10) according to one embodiment of the present disclosure.

According to one embodiment of the present disclosure, the pad portion (10) may include a pad electrode (110), a light separation layer (120), a plurality of insulating films (130), and a encapsulating film (140).

According to one embodiment of the present disclosure, the pad portion (10) may further include a substrate (100). For example, the pad electrode (110) of the pad portion (10) may be disposed on the substrate (100). The description of the substrate (100) is omitted as it overlaps with the above description.

According to one embodiment of the present disclosure, the pad electrode (110) may be disposed in the non-display area (NDA) of the display device (1) illustrated in FIG. 1. The pad electrode (110) is connected to a circuit film, such as an FPCB, and functions as a contact terminal that connects the circuit film and the underlying wiring to each other. For example, the pad electrode (110) may be connected to the flexible film (240) illustrated in FIG. 1.

According to one embodiment of the present disclosure, the pad electrode (110) may be a metal material having excellent reflectivity, such as aluminum (Al), aluminum alloy (AlNd), silver (Ag), etc., but is not limited thereto.

Although not shown in the drawing, a protective layer (not shown) may be further included on the pad electrode (110). The protective layer (not shown) may function to prevent the pad electrode (110) from being oxidized. The protective layer (not shown) may include, but is not limited to, titanium (Ti) and titanium nitride (TiN). For example, the protective layer (not shown) may be formed of a double layer of titanium (Ti) and titanium nitride (TiN).

According to one embodiment of the present disclosure, the light separation layer (120) may be disposed on the pad electrode (110). The light separation layer (120) may be formed to a thin thickness compared to the pad electrode (110). The light separation layer (120) is described in detail below.

According to one embodiment of the present disclosure, a plurality of insulating films (130) may be disposed spaced apart from each other on the pad electrode (110). The plurality of insulating films (130) may expose a portion of the upper surface of the pad electrode (110).

A light separation layer (120) may be disposed on the upper surface of the pad electrode (110) exposed by a plurality of insulating films (130).

Although FIG. 2 illustrates a plurality of insulating films (130) having a regular taper structure, the present disclosure is not limited thereto, and the plurality of insulating films (130) may have a reverse taper structure, and the taper angle may be vertical.

According to one embodiment of the present disclosure, the encapsulating film (140) may be disposed on the light separation layer (120). Specifically, the encapsulating film (140) may cover the upper surfaces of the light separation layer (120) and the plurality of insulating films (130).

According to one embodiment of the present disclosure, the pad portion (10) may include an open area (OA) and a non-open area (NOA). The open area (OA) refers to an area that does not overlap with a plurality of insulating films (130), and the non-open area (NOA) refers to an area that overlaps with a plurality of insulating films (130).

Typically, to connect pad electrodes and circuit films such as FPCBs, a process is required to selectively remove the encapsulating film by applying a laser to the upper portion of the pad. However, since the length of the pad portion is very short in consideration of the precision of laser equipment, it is difficult to irradiate the laser only onto the pad portion.

Since multiple insulating films made of silicon oxide (SiOx) or silicon nitride (SiNx) are disposed in the non-open area of the pad portion, they can be easily damaged by the laser. Therefore, the non-open area of the pad portion reacts faster to the laser irradiating the pad portion than the open area.

This can lead to the loss of the insulating film positioned in the non-open area before the encapsulating film positioned in the open area is removed by the laser irradiating the pad portion. Consequently, damage to the panel’s wiring can occur during the process of connecting the pad electrode and the circuit film. For example, damage can occur to the wiring positioned under the pad portion.

To solve the above problem, the pad portion (10) according to the present disclosure may include a light separation layer (120). Since the light separation layer (120) according to the present disclosure is disposed in the open area (OA), a peeling reaction may first occur in the light separation layer (120) disposed in the open area (OA) before the insulating film (130) disposed in the non-open area (NOA) is damaged. As a result, damage to the insulating film (130) disposed in the non-open area (NOA) may be minimized or reduced.

The light separation layer (120) may include at least one of an inorganic material, and an organic material. The inorganic material may include metal material and non-metal material.

According to one embodiment of the present disclosure, the metal material may include any one of silver (Ag), gold (Au), copper (Cu), and titanium (Ti) having high absorption and low reflection properties for a laser having an ultraviolet (UV) wavelength. In this case, the UV wavelength may be in the range of 10 to 400 nm.

For example, if the light separation layer (120) includes a metal material with low reflectivity and high absorption in the laser wavelength range being irradiated, electrons within the metal material are excited by the laser. As a result, the bonding strength of the metal within the metal material may be weakened. As a result, the light separation layer (120) may be easily peeled off from the pad electrode (110) when irradiated with the laser.

The non-metal material in the inorganic material may be a material having low transmittance. For example, the inorganic material may include either silicon nitride (SiNx) or silicon oxide (SiOx). The present disclosure is not limited thereto.

For example, when the light separation layer (120) includes an inorganic material, the bonding relationship between silicon (Si) atoms and nitrogen (N) atoms or the bonding relationship

between silicon (Si) atoms and oxygen (O) atoms may be weakened by a laser having high optical energy. As a result, nitrogen gas is generated, and the pressure of this nitrogen gas may cause the light separation layer (120) to be easily peeled off from the pad electrode (110).

The organic material may be a material having high conductivity and low resistance. For example, the organic material may include an organic material doped with an N-type dopant or an organic material doped with a P-type dopant.

For example, the organic material doped with an N-type dopant may be a lithium (Li)-doped electron transport layer (ETL).

For example, an organic material doped with a P-type dopant may be a hole injection layer (HIL).

For example, when the light separation layer (120) includes an organic material, the organic material is vulnerable to laser, so the light separation layer (120) made of the organic material can be easily peeled off from the pad electrode (110).

FIG. 3 is a cross-sectional view of a pad portion (11) according to another embodiment of the present disclosure.

Referring to FIG. 3, the insulating film (130) may include a first insulating film (131) and a second insulating film (132) disposed on the first insulating film (131).

FIG. 2 illustrates an insulating film (130) having a single-layer structure, and FIG. 3 illustrates an insulating film (130) having a two-layer structure. However, the present disclosure is not limited thereto, and the insulating film (130) may have a multi-layer structure of three or more layers.

Referring to FIG. 3, the encapsulating film (140) may include a first encapsulating film (141) and a second encapsulating film (142) disposed on the first encapsulating film (141).

FIG. 2 illustrates a single-layer structure of the encapsulating film (140), and FIG. 3 illustrates a two-layer structure of the encapsulating film (140). However, the present disclosure is not limited thereto, and the encapsulating film (140) may have a multi-layer structure of three or more layers.

According to one embodiment of the present disclosure, the light separation layer (120) may include a first light separation layer (121). Referring to FIG. 2, the first light separation layer (121) may be disposed on the pad electrode (110) while being spaced apart from the insulating

film (130). For example, the first light separation layer (121) may not be in contact with the insulating film (130) and may be disposed within the opening area (OA).

According to one embodiment of the present disclosure, the first light separation layer (121) may include at least one of an inorganic material, and an organic material. Descriptions of inorganic material, and organic material are omitted as they overlap with the preceding content.

According to one embodiment of the present disclosure, when the light separation layer (120) is made of a metal material or an organic material with excellent conductivity and is disposed to extend from the open area (OA) to the non-open area (NOA), when the pad electrode (110) is connected to the circuit film, a phenomenon in which current is unnecessarily conducted to the non-open area (NOA) may occur. Accordingly, the reliability of the display device (1) may be reduced.

Therefore, to solve the above problem, the first light separation layer (121) needs to be disposed apart from the insulating film (130).

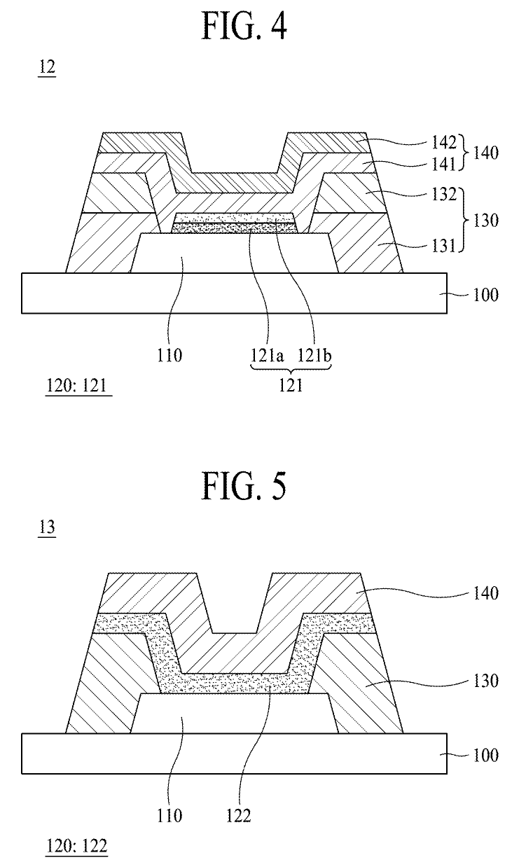

FIG. 4 is a cross-sectional view of a pad portion (12) according to another embodiment of the present disclosure.

According to one embodiment of the present disclosure, the first light separation layer (121) may be formed into a multilayer structure. For example, the first light separation layer (121) may include a first layer (121a) and a second layer (121b) disposed on the first layer (121a). The present disclosure is not limited thereto, and the first light separation layer (121) may be formed into a structure of three or more layers.

According to one embodiment of the present disclosure, the first layer (121a) of the first light separation layer (121) may be formed of either a metallic material or a non-metal material in an inorganic material, and the second layer (121b) of the first light separation layer (121) may be formed of the other of the metallic material and a non-metal material in the inorganic material. For example, when the first layer (121a) is formed of a metallic material, the second layer (121b) may be formed of a non-metal material, vice versa.

FIG. 5 is a cross-sectional view of a pad portion (13) according to another embodiment of the present disclosure.

Referring to FIG. 5, the light separation layer (120) may include a second light separation layer (122). Referring to FIG. 5, the second light separation layer (122) may be disposed in contact with the insulating film (130). For example, the second light separation layer (122) may

extend from the open area (OA) to the non-open area (NOA). In addition, the second light separation layer (122) may be disposed on the upper surface of the pad electrode (110) and may cover the side surface and the upper surface of the insulating film (130).

According to one embodiment of the present disclosure, the second light separation layer (122) may include an inorganic material (e.g., a non-metal material). The description of the inorganic material is omitted as it overlaps with the previous description.

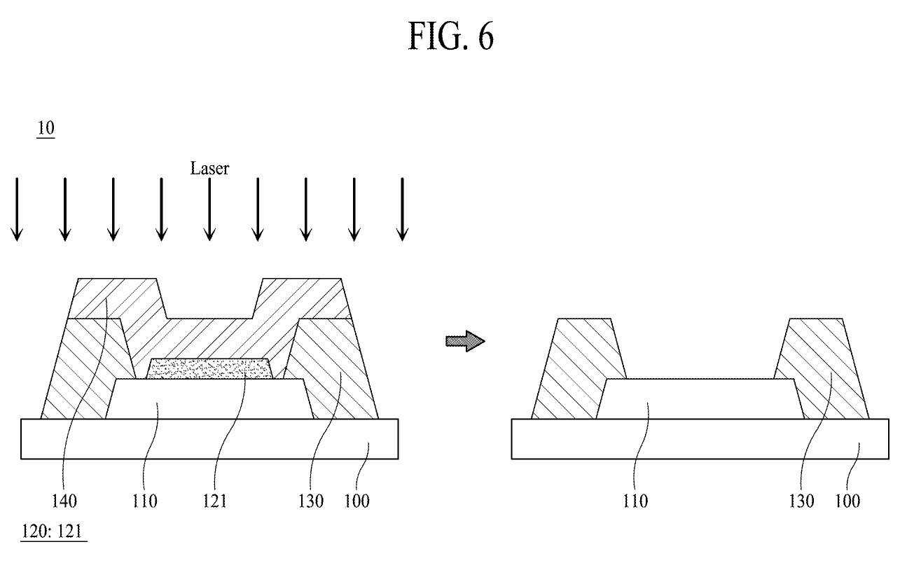

FIG. 6 is a drawing showing the laser process of the present disclosure.

Referring to FIG. 6, when a laser is irradiated to the pad portion (10) according to one embodiment of the present disclosure, the light separation layer (120) and the encapsulating film (140) can be removed.

According to the present disclosure, since the pad portion (10) includes a light separation layer (120), damage to the pad electrode (110) or the insulating film (130) can be minimized.

Thereafter, although not shown in the drawing, a conductive ball (not shown) may be formed on the pad electrode (110) exposed by the laser. The pad electrode (110) and the circuit film may be electrically connected through the conductive ball (not shown). However, the present disclosure is not limited thereto, and the pad electrode (110) and the circuit film may be configured to be integrally connected.

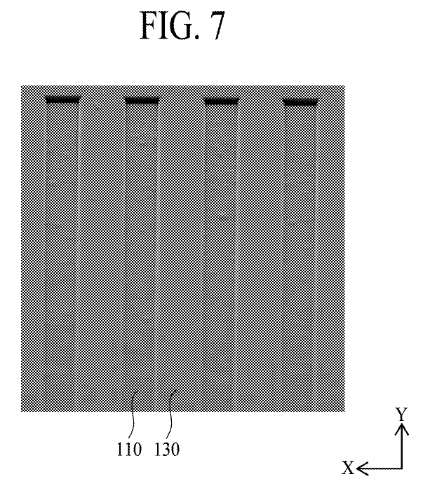

FIG. 7 is an image showing the planar shape of a pad portion (10) according to one embodiment of the present disclosure. FIG. 7 illustrates the shape of a pad electrode (110) and an insulating film (130) of the pad portion (10).

Referring to FIG. 7, a plurality of pad electrodes (110) of a pad portion (10) are disposed to be spaced apart from each other with a plurality of insulating films (130) therebetween. The plurality of pad electrodes (110) are disposed in parallel along a first direction (X) and may be disposed to extend based on a second direction (Y) perpendicular to the first direction (X). The plurality of insulating films (130) may be disposed to extend based on the second direction (Y).

According to the present disclosure, the following advantageous effects may be obtained.

According to one embodiment of the present disclosure, the pad portion includes a light separation layer, so that a peeling reaction can occur at the pad electrode before the insulating film is damaged by the laser.

According to one embodiment of the present disclosure, the pad portion includes a light separation layer, so that damage to the insulating film can be minimized or reduced.

In addition to the effects mentioned above, other features and advantages of the present disclosure are described below or may be clearly understood by those skilled in the art to which the present disclosure pertains from such description and explanation.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A pad portion, comprising:
a pad electrode having an upper surface;
a plurality of insulating films disposed on the pad electrode to be spaced apart from each other and exposing a portion of the upper surface of the pad electrode;
a light separation layer disposed on the portion of the upper surface of the pad electrode exposed by the plurality of insulating films; and
an encapsulating film disposed on the light separation layer.

2. The pad portion of claim 1,
wherein the light separation layer includes a first light separation layer disposed to be spaced apart from the plurality of insulating films.

3. The pad portion of claim 2,
wherein the first light separation layer includes at least one of an inorganic material, and an organic material, and wherein the inorganic material includes a metal material.

4. The pad portion of claim 3,
wherein the metal material includes
any one of silver (Ag), gold (Au), copper (Cu), and titanium (Ti).

5. The pad portion of claim 3,
wherein a non-metal material of the inorganic material includes any one of silicon nitride (SiNx) and silicon oxide (SiOx).

6. The pad portion of claim 3,
wherein the organic material includes an organic material doped with an N-type dopant or an organic material doped with a P-type dopant.

7. The pad portion of claim 3,
wherein the first light separation layer includes:
a first layer made of one of the metal material and a non-metal material in the inorganic material; and
a second layer made of the other of the metal material and the non-metal material in the inorganic material and disposed on the first layer.

8. The pad portion of claim 2,
wherein the light separation layer includes a second light separation layer disposed in contact with the plurality of insulating films.

9. The pad portion of claim 8,
wherein the second light separation layer covers side surfaces and upper surfaces of the plurality of insulating films.

10. The pad portion of claim 8,
wherein the second light separation layer includes an inorganic material, and
wherein the inorganic material includes any one of silicon nitride (SiNx) and silicon oxide (SiOx).

11. The pad portion of claim 1,
wherein the light separation layer is peeled off from the pad electrode when irradiated with a laser.

12. The pad portion of claim 1,
wherein the plurality of insulating films includes a first insulating film and a second insulating film disposed on the first insulating film, and
wherein the encapsulating film includes a first encapsulating film and a second encapsulating film disposed on the first encapsulating film.

13. A display device comprising,
a pad portion including:
a pad electrode having an upper surface;
a plurality of insulating films disposed on the pad electrode to be spaced apart from each other and exposing a portion of the upper surface of the pad electrode;
a light separation layer disposed on the portion of the upper surface of the pad electrode exposed by the plurality of insulating films; and
an encapsulating film disposed on the light separation layer.

14. The display device of claim 13,
wherein the light separation layer includes a first light separation layer disposed to be spaced apart from the plurality of insulating films.

15. The display device of claim 14,
wherein the first light separation layer includes at least one of an inorganic material, and an organic material, and wherein the inorganic material includes a metal material.

16. The display device of claim 15,
wherein the metal material includes any one of silver (Ag), gold (Au), copper (Cu), and titanium (Ti),
wherein a non-metal material of the inorganic material includes any one of silicon nitride (SiNx) and silicon oxide (SiOx), and
wherein the organic material includes an organic material doped with an N-type dopant or an organic material doped with a P-type dopant.

17. The display device of claim 15,
wherein the first light separation layer includes:
a first layer made of one of the metal material and a non-metal material in the inorganic material; and
a second layer made of the other of the metal material and the non-metal material in the inorganic material and disposed on the first layer.

18. The display device of claim 14,
wherein the light separation layer includes a second light separation layer disposed in contact with the plurality of insulating films.

19. The display device of claim 18,
wherein the second light separation layer covers side surfaces and upper surfaces of the plurality of insulating films, and
wherein the second light separation layer includes a non-metal material of an inorganic material, and
wherein the non-metal material includes any one of silicon nitride and silicon oxide.

20. The display device of claim 13,
wherein the plurality of insulating films includes a first insulating film and a second insulating film disposed on the first insulating film, and
wherein the encapsulating film includes a first encapsulating film and a second encapsulating film disposed on the first encapsulating film.
